(19) United States
(12) Patent Application Publication
(10) Pub. No.: US 2025/0261423 A1
(43) Pub. Date: Aug. 14, 2025

(54) FORMATION OF GATE ALL AROUND DEVICE

(71) Applicant: Applied Materials, Inc., Santa Clara, CA (US)

(72) Inventors: Wei Hong, Dublin, CA (US); Myungsun Kim, Pleasanton, CA (US); Joshua Rubnitz, Monte Sereno, CA (US); Chenfei Shen, San Jose, CA (US); Mehul Naik, San Jose, CA (US)

(73) Assignee: Applied Materials, Inc., Santa Clara, CA (US)

(21) Appl. No.: 18/438,067

(22) Filed: Feb. 9, 2024

(51) Int. Cl. H01L 29/66; H01L 29/06; H01L 29/423; H01L 29/775

(52) U.S. Cl. CPC H10D 64/018; H10D 30/014; H10D 30/43; H10D 30/6735; H10D 62/121; H10D 64/017

(57) ABSTRACT

Horizontal gate-all-around devices and methods of manufacturing the same are described. The hGAA devices comprise a self-aligned low-κ inner spacer adjacent to the replacement metal gate. The method includes growing the source/drain epitaxial material without an inner spacer and then forming a low-κ inner spacer material after dummy gate removal and nanosheet release.

### TECHNICAL FIELD

Embodiments of the present disclosure generally relate to semiconductor devices and more particularly to horizontal gate-all-around device structures and methods and apparatus for forming horizontal gate-all-around device structures.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. The hGAA structure provides good electrostatic control and can find broad adoption in complementary metal oxide semiconductor (CMOS) wafer manufacturing.

Logic gate performance is related to the characteristics of the materials used as well as the thickness and area of the structural layers. As some gate characteristics are adjusted, however, to accommodate device scaling, challenges arise. During the manufacture of horizontal gate-all-around (hGAA) devices, epitaxial material can grow on the nanosheet and not on the inner spacer. Such growth on the nanosheet leads to defective epitaxial material in the channel, resulting in insufficient GAA p-channel metal oxide semiconductor (PMOS) and n-channel metal oxide semiconductor (NMOS) drive current. Accordingly, there is a need for improved methods for forming gate-all-around devices.

### SUMMARY

One or more embodiments of the disclosure are directed to methods of forming a semiconductor device. In one or more embodiments, a method of forming a semiconductor device comprises: selectively etching a superlattice structure on a substrate, the superlattice structure comprising a plurality of semiconductor material layers and a corresponding plurality of release layers alternatingly arranged in a plurality of stacked pairs, to remove each of the plurality of release layers to form a plurality of voids in the superlattice structure, the plurality of semiconductor material layers extending between an epitaxial source region and an epitaxial drain region, the epitaxial source region and the epitaxial drain region substantially free of defects; and forming a self-aligned dielectric material in each of the plurality of voids on a sidewall of the epitaxial source region and on a sidewall of the epitaxial drain region.

Further embodiments of the disclosure are directed to a non-transitory computer readable medium including instructions, that, when executed by a controller of a processing chamber, causes the processing chamber to perform operations of: selectively etch a superlattice structure on a substrate, the superlattice structure comprising a plurality of semiconductor material layers and a corresponding plurality of release layers alternatingly arranged in a plurality of stacked pairs, to remove each of the plurality of release layers to form a plurality of voids in the superlattice structure, the plurality of semiconductor material layers extending between an epitaxial source region and an epitaxial drain region, the epitaxial source region and the epitaxial drain region substantially free of defects; and form a self-aligned dielectric material in each of the plurality of voids on a sidewall of the epitaxial source region and on a sidewall of the epitaxial drain region.

Additional embodiments of the disclosure are directed to gate-all-around semiconductor devices. In one or more embodiments, a gate-all-around (GAA) semiconductor device comprises: a superlattice structure on a substrate, the superlattice structure comprising a plurality of semiconductor material layers and a corresponding plurality of replacement metal gates adjacent to a self-aligned dielectric material comprising a low-κ dielectric material selected from one of more of silicon carbooxynitride (SiCON), silicon oxynitride (SiON), silicon nitride (SiN), and silicon carbide (SiC) and having a thickness in a range of from 3 nm to 15 nm, the plurality of semiconductor material layers extending between an epitaxial source region and an epitaxial drain region, wherein the epitaxial source region and the epitaxial drain region are substantially free of defects, and wherein there is substantially no seam between the self-aligned dielectric material and the epitaxial source region and the epitaxial drain region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a semiconductor device in accordance with some embodiments of the present disclosure;

FIGS. 2A-2D illustrate cross-section views of a GAA device during stages of a method of manufacture in accordance with some embodiments of the present disclosure;

FIGS. 3A-3D illustrate cross-section views of a GAA device during stages of a method of manufacture in accordance with some embodiments of the present disclosure;

FIG. 4 illustrates a cross-section view of a GAA device in accordance with one or more embodiments of the present disclosure; and

FIG. 5 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas”, and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated ID. Drain-to-source voltage is designated V_{DS}. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

In one or more embodiments, a horizontal gate-all-around (hGAA) or gate-all-around (GAA) transistor comprises a substrate having a top surface; a source region having a source and a source contact, the source region on the top surface of the substrate; a drain region having a drain and a drain contact, the drain region on the top surface of the substrate; a channel located between the source and the drain and having an axis that is substantially parallel to the top surface of the substrate; a gate enclosing the channel between the source region and the drain region; a dielectric layer overlying and in contact with one or more of the gate, the source contact, or the drain contact, and a gate spacer overlying the dielectric layer.

One or more embodiments of the disclosure are directed to methods of forming horizontal gate-all-around devices. Some embodiments advantageously provide methods that form an inner spacer having a self-aligned low-κ film post GAA nanosheet release. In one or more embodiments, a method of manufacturing a GAA device is advantageously provided where source/drain epitaxial material is grown post junction without the inner spacer and, subsequently, a self-aligned low-κ dielectric fill material is deposited post nanosheet release to form the inner spacer. Without intending to be bound by theory, it is thought that the method of one or more embodiments leads to source/drain epitaxial material substantially free of defects in the channel, resulting in sufficient PMOS and NMOS drive current. As used in this manner, the term “substantially free of defects” means that there are less than or equal to 5%, 2%, 1% or 0.5% of defects in the epitaxial material of the source/drain region. In one or more embodiments, the defect density of the source/drain is equivalent to the defect density in FinFETS having continuous source and drain cavities.

In the method of one or more embodiments, gate all-around transistors are fabricated using a standard process flow. The source/drain epitaxial material is formed without the presence of an inner spacer. After the dummy gate removal and the channel release, where the sacrificial silicon germanium (SiGe) epitaxial layers are removed to expose all sides of the silicon nano-slab, a self-aligned dielectric fill material is deposited to form the inner spacer.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

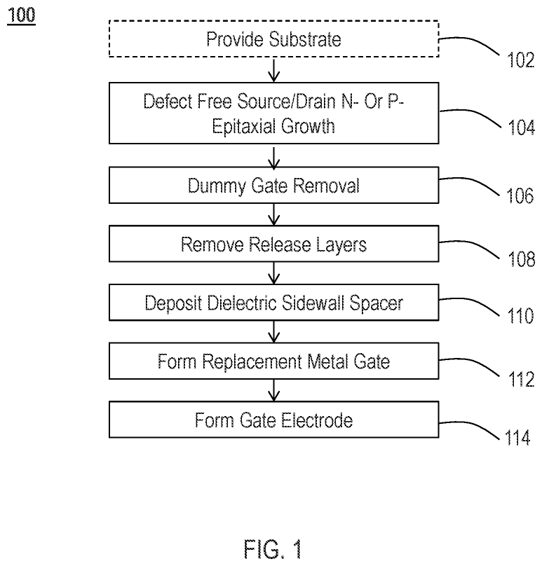

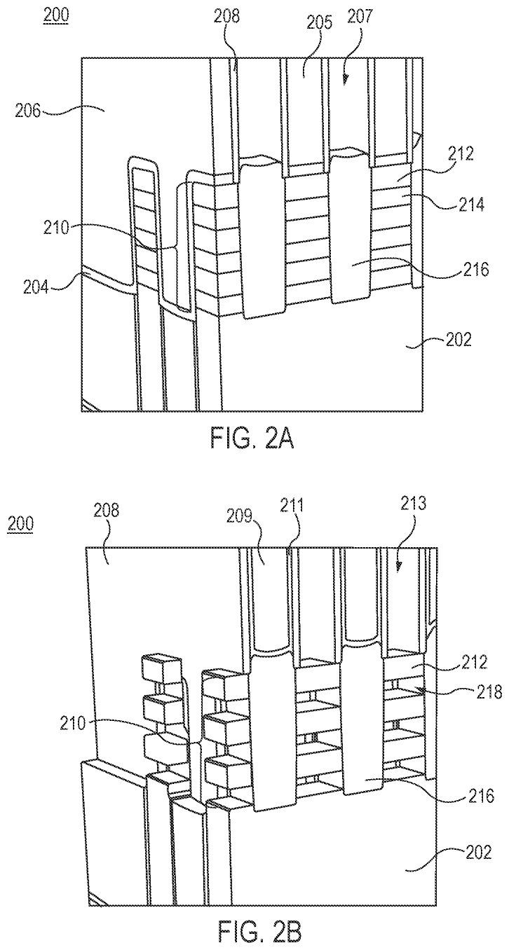

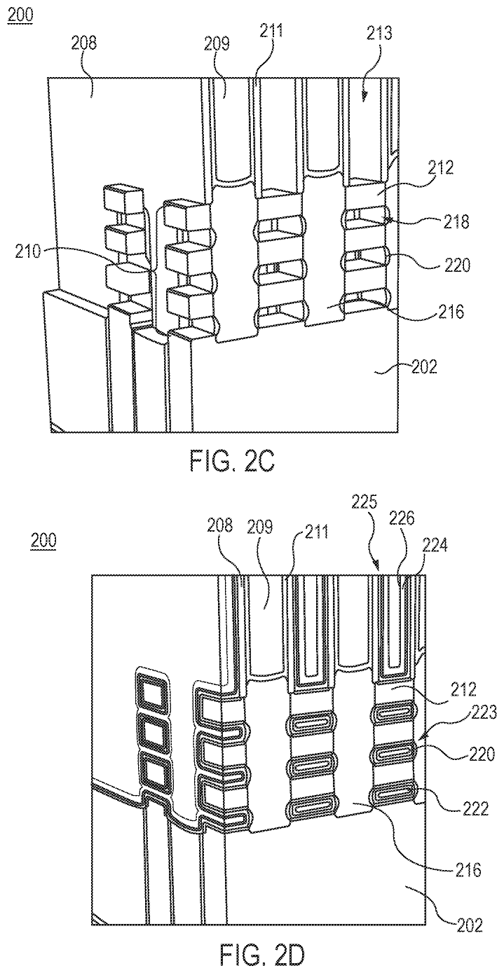

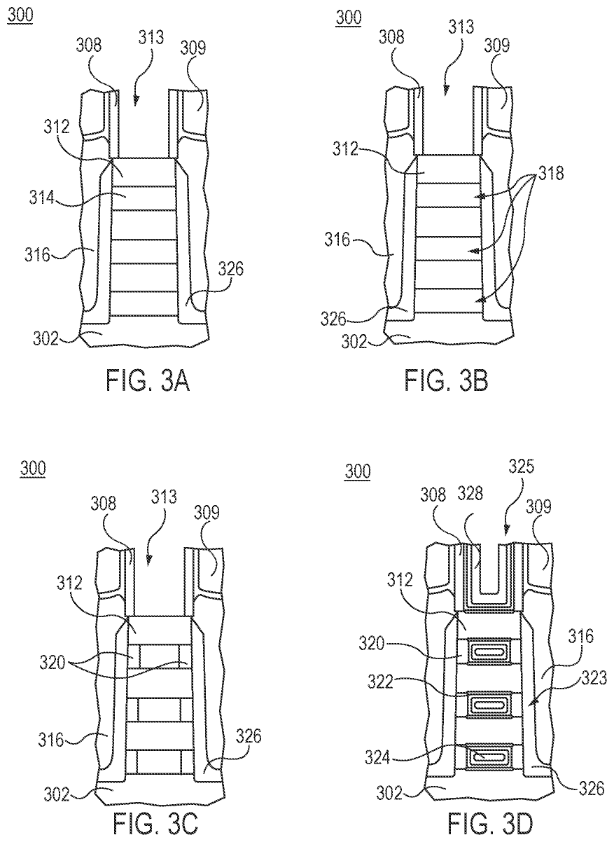

FIG. 1 illustrates a process flow diagram for a method 100 for forming a semiconductor device in accordance with some embodiments of the present disclosure. The method 100 is described below with respect to FIGS. 2A-2D and FIGS. 3A-3D, which depict the stages of fabrication of semiconductor structures in accordance with one or more embodiments of the present disclosure. FIGS. 2A-2D and FIGS. 3A-3D are cross-sectional views of an electronic device (e.g., a hGAA) according to one or more embodiments. The method 100 may be part of a multi-step fabrication process of a semiconductor device. Accordingly, the method 100 may be performed in any suitable process chamber coupled to a cluster tool. The cluster tool may include process chambers for fabricating a semiconductor device, such as chambers configured for etching, deposition, epitaxial growth, physical vapor deposition (PVD), chemical vapor deposition (CVD), oxidation, or any other suitable chamber used for the fabrication of a semiconductor device. In one or more embodiments, the method may be performed in a processing chamber or cluster tool without breaking vacuum.

The method 100 begins at operation 102, by providing a substrate 202 (as illustrated in FIG. 2A). In some embodiments, the substrate 202 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 202 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 202 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the substrate 202 may be doped to provide a high dose of dopant at a first location of the surface of the substrate 202 in order to prevent parasitic bottom device turn on. For example, in some embodiments, the surface of the substrate may have a dopant density about 10¹⁸ atoms/cm³ to about 10¹⁹ atoms/cm³.

At least one superlattice structure 210 is formed atop the top surface 203 of the substrate 202 (as depicted in FIG. 2A). The superlattice structure 210 comprises a plurality of semiconductor material layers 212 and a corresponding plurality of release layers 214 alternatingly arranged in a plurality of stacked pairs. In some embodiments the plurality of stacked groups of layers comprises a silicon (Si) and silicon germanium (SiGe) group. In some embodiments, the plurality of semiconductor material layers 212 and corresponding plurality of release layers 214 can comprise any number of lattice matched material pairs suitable for forming a superlattice structure 210. In some embodiments, the plurality of semiconductor material layers 212 and corresponding plurality of release layers 214 comprise from about 2 to about 50 pairs of lattice matched materials.

Typically, a parasitic device will exist at the bottom of the superlattice structure 210. In some embodiments, implantation of a dopant in the substrate 202, as discussed above, is used to suppress the turn on of the parasitic device. In some embodiments, the substrate 202 is etched so that the bottom portion of the superlattice structure 210 includes a substrate portion which is not removed, allowing the substrate portion to act as the bottom release layer of the superlattice structure 210.

In one or more embodiments, the thicknesses of the semiconductor material layers 212 and release layers 214 in some embodiments are in the range of from about 2 nm to about 50 nm, in the range of from about 3 nm to about 20 nm, or in a range of from about 2 nm to about 15 nm. In some embodiments, the average thickness of the semiconductor material layers 212 is within 0.5 to 2 times the average thickness of the release layers 214.

In some embodiments, a replacement gate structure (e.g., a dummy gate structure 205) is formed over and adjacent to the superlattice structure 210. The dummy gate structure 205 defines the channel region of the transistor device. The dummy gate structure 205 may be formed using any suitable conventional deposition and patterning process known in the art.

In some embodiments, sidewall spacers 208 are formed along outer sidewalls of the dummy gate structure 205. The sidewall spacers 208 of some embodiments comprise suitable insulating materials known in the art, for example, silicon nitride, silicon oxide, silicon oxynitride, silicon carbide, silicon oxycarbonitride (SiOCN), or the like. In some embodiments, the sidewall spacers 208 are formed using any suitable conventional deposition and patterning process known in the art, such as atomic layer deposition, plasma enhanced atomic layer deposition, plasma enhanced chemical vapor deposition or low-pressure chemical vapor deposition.

In some embodiments, a contact etch stop liner (CESL) nitride layer 211 is formed as a liner on the sidewall spacers 208 and on the top surface of the source/drain region 216. The contact etch stop liner (CESL) nitride layer may have any suitable thickness known to the skilled artisan. In one or more embodiments, the contact etch stop liner (CESL) nitride layer has any suitable thickness. The contact etch stop liner (CESL) nitride layer may comprise any suitable material. In one or more embodiments, the CSEL nitride layer 211 comprises one or more of silicon nitride, silicon oxide, silicon oxynitride, silicon carbide, silicon oxycarbonitride (SiOCN), or the like.

At operation 104, in one or more embodiments, an embedded source/drain region 216 is formed in a source trench and a drain trench, respectively. In some embodiments, the source region 216 is formed adjacent a first end of the superlattice structure 210 and the drain region 216 is formed adjacent a second, opposing end of the superlattice structure 210. In some embodiments, the source region 216 and/or drain region 216 are formed from any suitable semiconductor material, such as but not limited to silicon, germanium, silicon germanium, doped SiGe (PFET) or doped Si (NFET) where the dopants are B, P, Sn, C, or the like. In some embodiments, the source region 216 and drain region 216 may be formed using any suitable deposition process, such as an epitaxial deposition process. In one or more embodiments, the method 100 of manufacturing a GAA device advantageously grows/forms the source/drain epitaxial material post junction without the presence of an inner spacer inner spacer. Without intending to be bound by theory, it is thought that the method of one or more embodiments provides to epitaxial material in the source/drain region 216 that is substantially free of defects in the channel, resulting in sufficient PMOS and NMOS drive current. As used herein, the phrase “substantially free of defects” means that there are less than or equal to 5%, 2%, 1% or 0.5% of defects or irregularities in the epitaxial material that makes the source/drain. In one or more embodiments, the defect density is equivalent to the defect density in FinFETS having continuous source and drain cavities.

In some embodiments, an inter-layer dielectric (ILD) layer 209 is blanket deposited over the substrate 202, including the source/drain regions 207, the dummy gate structure 205, and the sidewall spacers 208. The ILD layer 209 may be deposited using a conventional chemical vapor deposition method (e.g., plasma enhance chemical vapor deposition and low-pressure chemical vapor deposition). In one or more embodiments, ILD layer 209 is formed from any suitable dielectric material such as, but not limited to, undoped silicon oxide, doped silicon oxide (e.g., BPSG, PSG), silicon nitride, silicon oxynitride, and silicon oxycarbonitride (SiOCN). In one or more embodiments, ILD layer 209 is then polished back using a conventional chemical mechanical planarization method to expose the top of the dummy gate structure 205. In some embodiments, the ILD layer 209 is polished to expose the top of the dummy gate structure 205 and the top of the sidewall spacers 208.

In operation 106, as shown in FIG. 2B, the dummy gate structure 205 is removed to expose the channel region 213 of the superlattice structure 210. The ILD layer 209 protects the source/drain regions 216 during the removal of the dummy gate structure 205. The dummy gate structure 205 may be removed using any conventional etching method such as a plasma dry etch, remote plasma dry etch, a wet etch, or combinations thereof. In some embodiments, the dummy gate structure 205 comprises polysilicon and the dummy gate structure 205 is removed by a selective etch process. In some embodiments, the dummy gate structure 205 comprises polysilicon and the superlattice structure 210 comprises alternating layers of silicon (Si) and silicon germanium (SiGe).

In operation 108, as illustrated in FIG. 20, the release layers 214 are selectively etched between the semiconductor material layers 212 in the superlattice structure 210. In one or more embodiments, an isotropic etch is performed on the release layers 214 to form one or more cavities 218 between the semiconductor material layers 212. As shown in FIG. 2C, each cavity 218 has a sidewall surface that is the epitaxial material of the source/drain region 216.

The isotropic etch process of operation 108 may be selected to remove sufficient material from superlattice structure 210 so that void/cavity 218 has any suitable target width. For example, in some embodiments, the isotropic etch process of operation 106 is performed so that cavity 218 has a target width of about 2 nm to about 10 nm. In other embodiments, cavity 218 bounded by the sidewall may have a target width of more than 10 nm or less than 2 nm, depending on the geometry of sidewall spacers 210, the concentration of n-dopants or p-dopants in heavily doped regions, and other factors.

The isotropic etch process of operation 108 may include any suitable etch process that is selective to the semiconductor material of the release layers 214. In some embodiments the isotropic etch process of operation 108 comprises one or more of a plasma dry etch, remote plasma dry etch, a wet etch, or combinations thereof. In some embodiments, the isotropic etch process of operation 108 comprises a dry etch process.

In one or more embodiments, where the superlattice structure 210 is composed of silicon layers and silicon germanium layers, the silicon germanium is selectively etched to form channel nanowires 212. The release layers 214, for example silicon germanium (SiGe), may be removed using any well-known etchant that is selective to the layers of the semiconductor material layers 212 where the etchant etches the layers of release layers 214 at a significantly higher rate than the layers of semiconductor material layers 212. In some embodiments, one or more of a plasma dry etch, a remote plasma dry etch, a wet etch, or combinations thereof may be used. The removal process(es) may be selective. The removal of the release layers 214 leaves voids 218 between the semiconductor material layers 212. The voids 218 between the semiconductor material layers 212 have a thickness of about 3 nm to about 20 nm. The remaining semiconductor material layers 212 form a vertical array of channel nanowires that are coupled to the source/drain regions 216. The channel nanowires run parallel to the top surface 203 of the substrate 202 and are aligned with each other to form a single column of channel nanowires. The formation of the source/drain region 216 and the formation of an optional lateral etch stop layer (not shown) advantageously provide self-alignment and structural integrity in the formation of the channel structure.

In such embodiments, the dry etch process may include a conventional plasma etch, or a remote plasma-assisted dry etch process. In a remote plasma-assisted dry etch process, the device may be exposed to H₂, NF₃, and/or NH₃ plasma species, e.g., plasma-excited hydrogen and fluorine species. For example, in some embodiments, the device 200 may undergo simultaneous exposure to H₂, NF₃, and NH₃ plasma. The wet etch process may include a hydrofluoric (HF) acid last process, i.e., the so-called “HF last” process, in which HF etching of the release layers 214 is performed that leaves the surface of the semiconductor material layers 212 hydrogen-terminated. Alternatively, any other liquid-based etch process may be employed. The etch process can be plasma or thermally based. The plasma processes can be any suitable plasma (e.g., conductively coupled plasma, inductively coupled plasma, microwave plasma).

In operation 110, as illustrated in FIG. 2C, a self-aligned dielectric material 220 is deposited on the sidewalls of the cavity/voids 218 formed by selective removal of the release layers 214. In one or more embodiments, the self-aligned dielectric material 220 comprises any suitable material known to the skilled artisan to form an inner spacer adjacent the source/drain regions 216. In one or more embodiments, the self-aligned dielectric material 220 comprises a low-κ dielectric material. As used herein, the term “low-κ dielectric material” refers to a material with a dielectric constant less than the dielectric constant of silicon dioxide. In some embodiments, the low-κ dielectric material has a k value less than 7 or less than 5. In one or more embodiments, the self-aligned dielectric material 220 may be formed by a selective deposition process, or by a selective deposition process with a selective removal process. In one or more embodiments, the self-aligned deposition process may be a low-κ selective PFCVD on boron (B) doped Si liner/SiGe EPI for inner spacer between P type contact.

In one or more embodiments, the low-κ dielectric material comprises any suitable low-κ dielectric material known to the skilled artisan. In some embodiments, the low-κ dielectric material is selected from silicon carbooxynitride (SiCON), silicon oxynitride (SiON), silicon nitride (SiN), silicon carbide (SiC), and the like. In some embodiments, the low-dielectric material is a flowable material.

In one or more embodiments, the self-aligned dielectric material 220 which forms the inner spacer has any suitable thickness. In some embodiments, the self-aligned dielectric material 220 has a thickness in a range of from greater than 0 nm to 15 nm, or in a range of from 3 nm to 15 nm, in a range of from 5 nm to 10 nm, or in a range of from 2 nm to 6 nm.

In one or more embodiments, the self-aligned dielectric material 220 is formed by a plasma enhanced chemical vapor deposition (PECVD) process. In one or more embodiments, the self-aligned dielectric material 220 is formed by a cyclic deposition, etch, deposition process. In other embodiments, the self-aligned dielectric material 220 is formed by flowable CVD and ALD. In one or more embodiments, the self-aligned dielectric material 220 forms on the sidewall of the epitaxial source/drain material such that there is substantially no seam formed between the self-aligned dielectric material 220 and the epitaxial source/drain material.

The method 100 of one or more embodiments advantageously provides an inner spacer having a self-aligned dielectric material 220 deposited post GAA nanosheet release. In one or more embodiments, the method 100 of manufacturing a GAA device 200 advantageously grows/form the source/drain epitaxial material 216 post junction without the inner spacer and, subsequently, the self-aligned low-K dielectric material 220 is deposited post nanosheet release to form the inner spacer. Without intending to be bound by theory, it is thought that the method 100 of one or more embodiments leads to epitaxial material in the source/drain region 216 that is substantially free of defects, resulting in sufficient PMOS and NMOS drive current.

In one or more embodiments, operation 112 of method 100 represents one or more post-inner spacer deposition processing operations. The one or more post-inner spacer deposition processes can be formed by any of the processes known to the skilled artisan for completion of the hGAA device, e.g., replacement metal gate 223 formation and gate electrode 225 formation. Referring to FIG. 2D, at operation 112, in one or more embodiments, a replacement metal gate 223 is formed or grown in the voids 218 between the semiconductor material layers 224 and adjacent to the self-aligned dielectric material 220. The replacement metal gate may include one or more of an oxide layer 222, a high-k dielectric material 224 and a work function material 226.

In the illustrated embodiment, an oxide layer 222 is formed or grown on the semiconductor material layers 212. The oxide layer 222 can be any suitable oxide formed by any suitable technique known to the skilled artisan.

In one or more embodiments, a high-k dielectric 224 is formed in the void 218 on the self-aligned dielectric material 220 and on the oxide layer 222. The high-k dielectric 224 can be any suitable high-k dielectric material deposited by any suitable deposition technique known to the skilled artisan. The high-k dielectric 224 of some embodiments comprises hafnium oxide. The high-k dielectric 224 may be formed using any suitable deposition process such as, but not limited to, atomic layer deposition (ALD) in order to ensure the formation of a layer having a uniform thickness around each of the semiconductor material layers 212.

In one or more embodiments, a work function material 226, such as titanium nitride (TiN), tungsten nitride (WN), tantalum nitride (TaN), molybdenum nitride (MoN), or the like is deposited on the high-k dielectric 224. The work function material 226 may be formed using any suitable deposition process such as, but not limited to, atomic layer deposition (ALD) in order to ensure the formation of a layer having a uniform thickness.

In some embodiments, referring to FIG. 1 and FIG. 2D, at operation 114, a gate electrode 225 is formed on the device 200. The gate electrode 225 may be formed from any suitable gate electrode material known in the art. The gate electrode material is deposited using any suitable deposition process such as atomic layer deposition (ALD). The resultant device formed using the method described herein is a horizontal gate all around device, in accordance with an embodiment of the present disclosure. Some embodiments of the disclosure are directed to horizontal gate-all-around devices comprising a self-aligned dielectric material 220 as an inner spacer adjacent to the replacement metal gate 223 in the channel between source and drain regions 216.

FIGS. 3A-3D illustrate a cross-sectional view of an electronic device being processed according to the method illustrated in FIG. 1. FIGS. 3A to 3D differ from the cross-sectional view of FIGS. 2A to 2D in that FIGS. 3A to 3D are not three dimensional. As described above, the method 100 begins at operation 102, by providing a substrate 302.

At least one superlattice structure 310 is formed atop the top surface of the substrate 302 (as depicted in FIG. 3A). As described above with respect to FIGS. 2A to 2D, the superlattice structure 310 comprises a plurality of semiconductor material layers 312 and a corresponding plurality of release layers 314 alternatingly arranged in a plurality of stacked pairs.

In some embodiments, a replacement gate structure (e.g., a dummy gate structure, not illustrated) is formed over and adjacent to the superlattice structure 310. The dummy gate structure defines the channel region of the transistor device.

In some embodiments, sidewall spacers 308 are formed along outer sidewalls of the dummy gate structure. The sidewall spacers 308 of some embodiments comprise suitable insulating materials known in the art, for example, silicon nitride, silicon oxide, silicon oxynitride, silicon carbide, or the like. As described above with respect to FIGS. 2A-2D, in some embodiments, a contact etch stop liner (CESL) nitride layer 311 is formed as a liner on the sidewall spacers 308 and on the top surface of the source/drain region 316. The contact etch stop liner (CESL) nitride layer may comprise any suitable material. In one or more embodiments, the CESL nitride layer 311 comprises one or more of silicon nitride, silicon oxide, silicon oxynitride, silicon carbide, silicon oxycarbonitride (SiOCN), or the like.

In some embodiments, an embedded source/drain region 316 is formed in a source trench and a drain trench, respectively. In some embodiments, the source region 316 is formed adjacent a first end of the superlattice structure 310 and the drain region 316 is formed adjacent a second, opposing end of the superlattice structure 310. In some embodiments, the source region 316 and/or drain region 316 are formed from any suitable semiconductor material, such as but not limited to silicon, germanium, silicon germanium, doped-silicon, doped-silicon germanium, where the dopant is one or more of boron (B), phosphorus (P), carbon (C), tin (Sn), or the like. In one or more specific embodiments, the source/drain region 316 comprises boron (B) doped epitaxial silicon germanium (SiGe) for PMOS. In other embodiments, the source/drain region 316 comprises phosphorus (P) doped epitaxial silicon (Si) for NMOS. In some embodiments, the source region 316 and drain region 316 may be formed using any suitable deposition process, such as an epitaxial deposition process. In one or more embodiments, the method 100 of manufacturing a GAA device advantageously grows/forms the source/drain epitaxial material post junction without the presence of an inner spacer inner spacer. Without intending to be bound by theory, it is thought that the method of one or more embodiments leads to epitaxial material in the source/drain region 316 that is substantially free of defects in the channel, resulting in sufficient PMOS drive current. As used herein, the phrase “substantially free of defects” means that there are less than or equal to 5%, 2%, 1% or 0.5% of defects or irregularities in the epitaxial material that makes the source/drain.

In one or more embodiments, a liner 326 is grown from the silicon sidewall. In one or more embodiments, the liner 326 comprises any suitable material known to the skilled artisan. In specific embodiments, the liner 326 comprises either boron (B) doped epitaxial silicon liner, e.g., for PMOS, or arsenic (As) doped epitaxial silicon liner, e.g., for NMOS. In one or more embodiments, the liner 326 advantageously allows defect free epitaxial material to form the source/drain region 316. In one or more embodiments, the liner 326 is used to form the sidewall for the deposition of the subsequent self-aligned dielectric material 320.

In some embodiments, as described above with respect to FIGS. 2A-2D, an inter-layer dielectric (ILD) layer 309 is blanket deposited over the substrate 302, including the source/drain regions 316, the dummy gate structure, and the sidewall spacers 308.

In operation 106, as shown in FIG. 3A, and as described above with respect to FIGS. 2A-2D, the dummy gate structure is removed to expose the channel region 313 of the superlattice structure 310. The ILD layer 309 protects the source/drain regions 316 during the removal of the dummy gate structure.

In operation 108, as illustrated in FIG. 3B, the release layers 314 are selectively etched between the semiconductor material layers 312 in the superlattice structure 310. In one or more embodiments, an isotropic etch is performed on the release layers 314 to form one or more voids/cavities 318 between the semiconductor material layers 312. As shown in FIG. 3B, each cavity 318 has a sidewall surface that is the epitaxial material of the source/drain region 316.

In operation 110, as illustrated in FIG. 3C, and as described above with respect to FIGS. 2A-2D, a self-aligned dielectric material 320 is deposited on the sidewalls of the cavity/voids 318 formed by selective removal of the release layers 2314. In one or more embodiments, the self-aligned dielectric material 320 comprises any suitable material known to the skilled artisan to form an inner spacer adjacent the source/drain regions 316. In one or more embodiments, the self-aligned dielectric material 320 comprises a low-κ dielectric material. In some embodiments, the low-K dielectric material has a k value less than 7 or less than 5. In some embodiments, the low-κ dielectric material is selected from silicon carbooxynitride (SiCON), silicon oxynitride (SiON), silicon nitride (SiN), silicon carbide (SiC), and the like. In some embodiments, the low-κ dielectric material is a flowable material.

In one or more embodiments, the self-aligned dielectric material 320 which forms the inner spacer has any suitable thickness. In some embodiments, the self-aligned dielectric material 320 has a thickness in a range of from greater than 0 nm to 15 nm, or in a range of from 3 nm to 15 nm, in a range of from 5 nm to 10 nm, or in a range of from 2 nm to 6 nm.

In one or more embodiments, the self-aligned dielectric material 320 is formed by a plasma enhanced chemical vapor deposition (PECVD) process. In one or more embodiments, the self-aligned dielectric material 320 is formed by a cyclic deposition, etch, deposition process. In other embodiments, the self-aligned dielectric material 320 is formed by flowable CVD and ALD. In one or more embodiments, the self-aligned dielectric material 320 forms on the sidewall of the epitaxial source/drain material 316 such that there is substantially no seam formed between the self-aligned dielectric material 320 and the epitaxial source/drain material 316.

The method 100 of one or more embodiments advantageously provides an inner spacer having a self-aligned dielectric material 320 deposited post GAA nanosheet release. In one or more embodiments, the method 100 of manufacturing a GAA device 300 advantageously grows/form the source/drain epitaxial material 316 post junction without the inner spacer and, subsequently, the self-aligned low-K dielectric material 320 is deposited post nanosheet release to form the inner spacer. Without intending to be bound by theory, it is thought that the method 100 of one or more embodiments leads to epitaxial material in the source/drain region 316 that is substantially free of defects, resulting in sufficient PMOS and NMOS drive current.

As detailed above with respect to FIG. 2D, in one or more embodiments, operation 112 of method 100 represents one or more post-inner spacer deposition processing operations. The one or more post-inner spacer deposition processes can be any of the processes known to the skilled artisan for completion of the hGAA device, e.g., replacement metal gate 323 formation and gate electrode 325 formation. Referring to FIG. 3D, at operation 112, in one or more embodiments, a replacement metal gate 323 is formed or grown in the voids 318 between the semiconductor material layers 312 and adjacent to the self-aligned dielectric material 320. The replacement metal gate 323 may include one or more of an oxide layer 322, a high-k dielectric material 324 and a work function material 328.

In the illustrated embodiment, an oxide layer 322 is formed or grown on the semiconductor material layers 312. In one or more embodiments, a high-k dielectric 324 is formed in the void 318 on the self-aligned dielectric material 320 and on the oxide layer 322. The high-k dielectric 324 can be any suitable high-k dielectric material deposited by any suitable deposition technique known to the skilled artisan. The high-k dielectric 324 of some embodiments comprises hafnium oxide. The high-k dielectric 324 may be formed using any suitable deposition process such as, but not limited to, atomic layer deposition (ALD) in order to ensure the formation of a layer having a uniform thickness around each of the semiconductor material layers 312.

In one or more embodiments, a work function material 328, such as titanium nitride (TiN), tungsten nitride (WN), tantalum nitride (TaN), molybdenum nitride (MoN), or the like is deposited on the high-k dielectric 324. The work function material 328 may be formed using any suitable deposition process such as, but not limited to, atomic layer deposition (ALD) in order to ensure the formation of a layer having a uniform thickness.

In some embodiments, referring to FIG. 1 and FIG. 3D, at operation 114, a gate electrode 325 is formed on the device 300. The gate electrode 325 may be formed from any suitable gate electrode material known in the art. The gate electrode material is deposited using any suitable deposition process such as atomic layer deposition (ALD). The resultant device formed using the method described herein is a horizontal gate all around device, in accordance with an embodiment of the present disclosure. Some embodiments of the disclosure are directed to horizontal gate-all-around devices comprising a self-aligned dielectric material 320 as an inner spacer adjacent to the replacement metal gate 323 in the channel between source and drain regions 316.

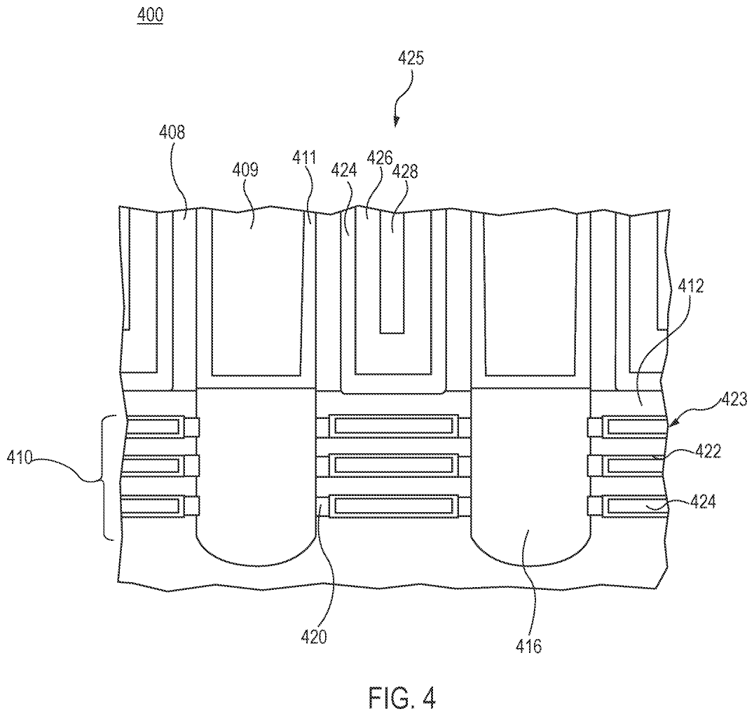

FIG. 4 illustrates a cross-section view of a GAA device in accordance with one or more embodiments of the present disclosure. The device 400 includes a self-aligned dielectric material 420 adjacent to a replacement metal gate 423 and adjacent to the source/drain regions 416. In one or more embodiments, the self-aligned dielectric material 420 forms on the sidewall of the epitaxial source/drain material 416 such that there is substantially no seam formed between the self-aligned dielectric material 420 and the epitaxial source/drain material 416.

The superlattice structure 410 includes a plurality of semiconductor material layers 412 alternatingly arranges with a plurality of replacement metal gate structures 423 having a self-aligned dielectric material 420 adjacent to the replacement metal gate structure 423. An oxide layer 422 may be formed on the metal gate structure 423. A gate electrode 425 is formed on the superlattice structure 410. The gate electrode 425 includes a high-K dielectric layer 424 a work function material 426, and a conductive material 428. An interlayer dielectric 409 is deposited on the source/drain region 416, and sidewall spacers 408 as formed adjacent to the gate electrode 425 and the interlayer dielectric 409. In some embodiments, a contact etch stop liner (CESL) nitride layer 411 is formed as a liner on the sidewall spacers 408 and on the top surface of the source/drain region 416.

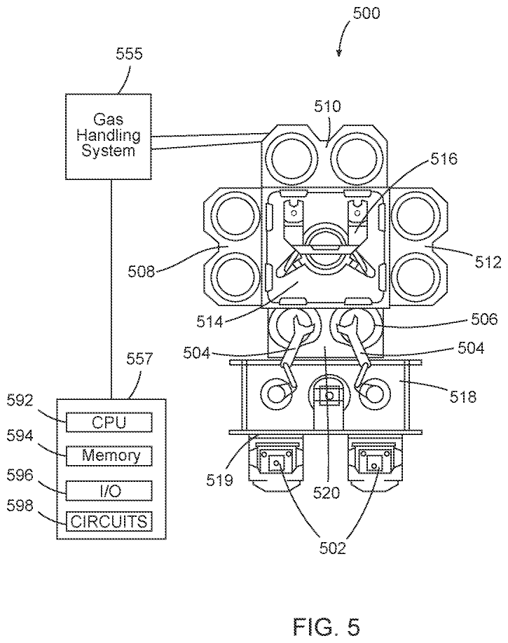

Additional embodiments of the disclosure are directed to processing tools 500 for the formation of the GAA devices and methods described, as shown in FIG. 5. A variety of multi-processing platforms and processing systems may be utilized. The cluster tool 500 includes at least one central transfer station 514 with a plurality of sides. A robot 516 is positioned within the central transfer station 514 and is configured to move a robot blade and a wafer to each of the plurality of sides.

The cluster tool 500 comprises a plurality of processing chambers 508, 510, and 512, also referred to as process stations, connected to the central transfer station. The various processing chambers provide separate processing regions isolated from adjacent process stations. The processing chamber can be any suitable chamber including, but not limited to, a preclean chamber, a deposition chamber, an annealing chamber, an etching chamber, a selective etching chamber, and the like. The particular arrangement of process chambers and components can be varied depending on the cluster tool and should not be taken as limiting the scope of the disclosure.

In some embodiments, the cluster tool 500 includes an etching chamber for selectively removing the release layers. The etching chamber of some embodiments comprises one or more a fluorine-based dry etching chamber. In some embodiments, the cluster tool 500 includes a pre-cleaning chamber connected to the central transfer station.

In the embodiment shown in FIG. 5, a factory interface 518 is connected to a front of the cluster tool 500. The factory interface 518 includes chambers 502 for loading and unloading on a front 519 of the factory interface 518.

The size and shape of the loading chamber and unloading chamber 502 can vary depending on, for example, the substrates being processed in the cluster tool 500. In the embodiment shown, the loading chamber and unloading chamber 502 are sized to hold a wafer cassette with a plurality of wafers positioned within the cassette.

Robots 504 are within the factory interface 518 and can move between the loading and unloading chambers 502. The robots 504 are capable of transferring a wafer from a cassette in the loading chamber 502 through the factory interface 518 to load lock chamber 520. The robots 504 are also capable of transferring a wafer from the load lock chamber 520 through the factory interface 518 to a cassette in the unloading chamber 502.

The robot 516 of some embodiments is a multi-arm robot capable of independently moving more than one wafer at a time. The robot 516 is configured to move wafers between the chambers around the transfer chamber 514. Individual wafers are carried upon a wafer transport blade that is located at a distal end of the first robotic mechanism.

A system controller 557 is in communication with the robot 516, and a plurality of processing chambers 508, 510 and 512. The system controller 557 can be any suitable component that can control the processing chambers and robots. For example, the system controller 557 can be a computer including a central processing unit (CPU) 592, memory 594, inputs/outputs 596, suitable circuits 598, and storage.

Processes may generally be stored in the memory of the system controller 357 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the system controller 557 has a configuration to control the deposition of the self-aligned dielectric material in the void/cavity between the semiconductor material layers to form the inner spacer.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising an etching chamber; and a controller connected to the central transfer station and the plurality of process stations, the controller configured to activate the robot to move the wafer between process stations, and to control a process occurring in each of the process stations.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, comprising:
selectively etching a superlattice structure on a substrate, the superlattice structure comprising a plurality of semiconductor material layers and a corresponding plurality of release layers alternatingly arranged in a plurality of stacked pairs, to remove each of the plurality of release layers to form a plurality of voids in the superlattice structure, the plurality of semiconductor material layers extending between an epitaxial source region and an epitaxial drain region, the epitaxial source region and the epitaxial drain region substantially free of defects; and
forming a self-aligned dielectric material in each of the plurality of voids on a sidewall of the epitaxial source region and on a sidewall of the epitaxial drain region.

2. The method of claim 1, wherein self-aligned dielectric material comprises a low-K dielectric material.

3. The method of claim 2, wherein the low-κ dielectric material comprises one of more of silicon carbooxynitride (SiCON), silicon oxynitride (SiON), silicon nitride (SiN), silicon carbide (SiC), and the like.

4. The method of claim 3, wherein the low-κ dielectric material comprises one of more of silicon carbooxynitride (SiCON).

5. The method of claim 1, wherein the self-aligned dielectric material has a thickness in a range of from 3 nm to 15 nm.

6. The method of claim 5, wherein the self-aligned dielectric material has a thickness in a range of from 2 nm to 6 nm.

7. The method of claim 1, wherein forming the self-aligned dielectric material comprises a flowable CVD and ALD process.

8. The method of claim 1, further comprising forming the epitaxial source region adjacent a first end of the superlattice structure and the epitaxial drain region adjacent a second opposing end of the superlattice structure prior to selectively etching the release layers.

9. The method of claim 8, further comprising forming a liner layer on the epitaxial source region and on the epitaxial drain region, the liner layer comprising boron (B) doped epitaxial silicon or arsenic (As) doped epitaxial silicon.

10. The method of claim 1, wherein the plurality of semiconductor material layers comprise silicon (Si), and wherein the plurality of release layers comprise silicon germanium (SiGe).

11. The method of claim 1, wherein the method is performed in a processing chamber without breaking vacuum.

12. The method of claim 1, further comprising forming a replacement gate in the plurality of voids adjacent to the self-aligned dielectric material.

13. The method of claim 12, wherein the replacement gate comprises one or more of a high-κ dielectric material, an oxide layer, and a work function material.

14. The method of claim 1, further comprising forming a gate electrode on a top surface of the superlattice structure.

15. The method of claim 14, wherein the gate electrode comprises one or more of a high-κ dielectric material, a work function material, and a conductive material.

16. A non-transitory computer readable medium including instructions, that, when executed by a controller of a processing chamber, causes the processing chamber to perform operations of:
selectively etch a superlattice structure on a substrate, the superlattice structure comprising a plurality of semiconductor material layers and a corresponding plurality of release layers alternatingly arranged in a plurality of stacked pairs, to remove each of the plurality of release layers to form a plurality of voids in the superlattice structure, the plurality of semiconductor material layers extending between an epitaxial source region and an epitaxial drain region, the epitaxial source region and the epitaxial drain region substantially free of defects; and
form a self-aligned dielectric material in each of the plurality of voids on a sidewall of the epitaxial source region and on a sidewall of the epitaxial drain region.

17. The non-transitory computer readable medium of claim 16, further including instructions, that, when executed by a controller of a processing chamber, causes the processing chamber to perform further operations of:
form the epitaxial source region adjacent a first end of the superlattice structure and the epitaxial drain region adjacent a second opposing end of the superlattice structure prior to selectively etching the release layers.

18. The non-transitory computer readable medium of claim 16, further including instructions, that, when executed by a controller of a processing chamber, causes the processing chamber to perform further operations of:
form a replacement gate in the plurality of voids adjacent to the self-aligned dielectric material.

19. The non-transitory computer readable medium of claim 16, further including instructions, that, when executed by a controller of a processing chamber, causes the processing chamber to perform further operations of:
form a gate electrode on a top surface of the superlattice structure.

20. A gate-all-around (GAA) semiconductor device comprising:
a superlattice structure on a substrate, the superlattice structure comprising a plurality of semiconductor material layers and a corresponding plurality of replacement metal gates adjacent to a self-aligned dielectric material comprising a low-κ dielectric material selected from one of more of silicon carbooxynitride (SiCON), silicon oxynitride (SiON), silicon nitride (SiN), or silicon carbide (SiC), and having a thickness in a range of from 3 nm to 15 nm, the plurality of semiconductor material layers extending between an epitaxial source region and an epitaxial drain region,
wherein the epitaxial source region and the epitaxial drain region are substantially free of defects, and
wherein there is substantially no seam between the self-aligned dielectric material and the epitaxial source region and the epitaxial drain region.
